(19) United States
(12) Patent Application Publication
(10) Pub. No.: US 2025/0183129 A1
(43) Pub. Date: Jun. 5, 2025

(54) THERMAL ENHANCED ELECTRONIC DEVICE PACKAGE

(71) Applicant: Texas Instruments Incorporated, Dallas, TX (US)

(72) Inventors: Ashok Prabhu, San Jose, CA (US); Hau Nguyen, San Jose, CA (US)

(21) Appl. No.: 18/524,383

(22) Filed: Nov. 30, 2023

(51) Int. Cl. H01L 23/495; H01L 21/56; H01L 23/00; H01L 23/31; H01L 23/36

(52) U.S. Cl. CPC H01L 23/49541; H01L 21/561; H01L 23/3107; H01L 23/36; H01L 24/16; H01L 24/81; H01L 24/13; H01L 2224/13147; H01L 2224/16245; H01L 2224/81815

(57) ABSTRACT

An electronic device includes: opposite first and second sides; opposite third and fourth sides; a molded package structure; a semiconductor die having a backside metal structure exposed outside the molded package structure along the second side; and conductive metal first leads along the third and fourth sides, each one of the first leads having a first portion and a second portion, the first portion having a side exposed outside the molded package structure along the first side, and the second portion enclosed by the molded package structure and spaced apart from the first side by a non-zero distance.

### BACKGROUND

The thermal performance of an electronic device can sometimes be improved by attaching a heat sink to and/or forcing air flow across the top side of the device. Heat removal can help device performance and extend service life. A semiconductor die and its components of an electronic device may benefit from heat removal from the die, for example, by exposing a die backside or backside metal of the die outside a package. However, exposing die backside metal in a cost effective manner is difficult due to mold flash and other molding equipment and process limitations and variations in device thickness cause by dimensional tolerances of lead frames, die attach adhesive and semiconductor dies as well as tolerance from mold cap tooling and processes. An alternative is to over mold the die backside and then expose the die backside by grinding, followed by depositing metal on backside of the die, but this is a complicated and costly process flow with added processing steps and risk of die chipping or cracking due to mechanical stress during grinding.

### SUMMARY

In one aspect, an electronic device includes opposite first and second sides, opposite third and fourth sides, a molded package structure, a semiconductor die, and conductive metal first leads along the third and fourth sides. The semiconductor die has a backside metal structure exposed outside the molded package structure along the second side. The individual conductive metal first leads have first and second portions with the first portion having a side exposed outside the molded package structure along the first side, and the second portion enclosed by the molded package structure and spaced apart from the first side by a non-zero distance.

In another aspect, a system includes a circuit board having conductive metal pads and an electronic device attached to the circuit board. The electronic device includes opposite first and second sides, opposite third and fourth sides, a molded package structure, a semiconductor die, and conductive metal first leads along the third and fourth sides. The semiconductor die has a backside metal structure exposed outside the molded package structure along the second side. The individual conductive metal first leads have first and second portions with the first portion having a side exposed outside the molded package structure and connected to a respective one of the conductive metal pads along the first side, and the second portion enclosed by the molded package structure and spaced apart from the first side by a non-zero distance.

In a further aspect, a method fabricating an electronic device includes: mounting a first side of a semiconductor die on a unit area of a lead frame; electrically connecting conductive terminals along the first side of the semiconductor die to raised second portions of respective prospective first leads along two opposite lateral sides of the unit area that are spaced apart from one another along a first direction; and performing a molding process with a mold having a first mold portion that engages a backside metal structure along an opposite second side of the semiconductor die and a second mold portion that engages bottom sides of lower first portions of the prospective first leads in the unit area to form a molded package structure that extends through multiple unit areas along a column of the lead frame, exposes the backside metal structure, encloses the second portions of the prospective first leads, and exposes the bottom sides of the lower first portions of the prospective first leads in the unit area. The method also includes separating the column from an adjacent second column of the lead frame along an orthogonal second direction to form first leads with the lower first portions and the raised second portions along the two opposite lateral sides of the unit area and cutting through the molded package structure along the first direction to separate an electronic device of the unit area from the lead frame.

In another aspect, a lead frame includes unit areas arranged in an array with rows along a first direction and columns along an orthogonal second direction. The individual unit areas have prospective first leads along two opposite lateral sides of the unit area that are spaced apart from one another along the first direction, and prospective second leads along two opposite lateral ends of the unit area that are spaced apart from one another along the second direction. The individual prospective first leads have a lower first portion and a raised second portion, the first portion having a bottom side, and the second portion having a bottom side spaced apart from the bottom side of the first portion by a non-zero distance. The lead frame also includes first tie bars connected to the prospective first leads of the unit areas along a column of the array and second tie bars connected to the prospective second leads along adjacent rows of the array.

### BRIEF DESCRIPTION OF THE DRAWINGS

FIG. 1 is a top perspective view of a system with an electronic device mounted to a circuit board and with a die backside metal thermal pad exposed outside the top of the electronic device package.

FIG. 1A is a bottom perspective view of the electronic device of FIG. 1.

FIG. 1B is a sectional side elevation view of the electronic device taken along line 1B-1B of FIGS. 1 and 1A.

FIG. 1C is a side elevation view of the electronic device of FIGS. 1-1B.

FIG. 1D is a partial sectional side elevation view of another system with the electronic device of FIGS. 1-1B installed on a circuit board and a heat sink installed on the die backside metal thermal pad of the electronic device.

FIG. 2 is a flow diagram showing a method for making an electronic device according to another aspect.

FIG. 3 is a partial sectional side elevation view of a semiconductor wafer undergoing a backside metallization process.

FIG. 4 is a top perspective view of the semiconductor wafer of FIG. 3 undergoing a die separation process.

FIG. 5 is a partial sectional side elevation view of a unit area of a lead frame panel array with prospective upset first leads.

FIG. 6 is a partial sectional side elevation view of the lead frame panel array undergoing a die attach process.

FIG. 7 is a partial sectional side elevation view of the lead frame panel array undergoing a solder reflow electrical connection process.

FIG. 8 is a partial sectional side elevation view of the lead frame panel array undergoing a column molding process.

FIG. 8A is a partial top perspective view of the lead frame panel array after removal from the mold in the column molding process.

FIG. 9 is a partial sectional side elevation view of the lead frame panel array undergoing a flash removal process.

FIG. 10 is a partial sectional side elevation view of the lead frame panel array undergoing a post flash removal baking process.

FIG. 11 is a partial sectional side elevation view of the lead frame panel array undergoing a plating process.

FIG. 12 is a partial sectional side elevation view of the lead frame panel array undergoing a column direction separation process that trims the upset first leads.

FIG. 12A is a partial top perspective view of the lead frame panel undergoing a column direction separation process.

FIG. 13 is a partial top perspective view of the lead frame panel array undergoing a row direction separation process.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. In the following discussion and in the claims, the terms “including”, “includes”, “having”, “has”, “with”, or variants thereof are intended to be inclusive in a manner similar to the term “comprising”, and thus should be interpreted to mean “including, but not limited to”.

Unless otherwise stated, “about,” “approximately,” or “substantially” preceding a value means +/−10 percent of the stated value. One or more operational characteristics of various circuits, systems and/or components are hereinafter described in the context of functions which in some cases result from configuration and/or interconnection of various structures when circuitry is powered and operating. One or more structures, features, aspects, components, etc., may be referred to herein as first, second, third, etc., such as first and second terminals, first, second, and third, wells, etc., for ease of description in connection with a particular drawing, where such are not to be construed as limiting with respect to the claims. Various disclosed structures and methods of the present disclosure may be beneficially applied to manufacturing an electronic device such as an integrated circuit. While such examples may be expected to provide various improvements, no particular result is a requirement of the present disclosure unless explicitly recited in a particular claim.

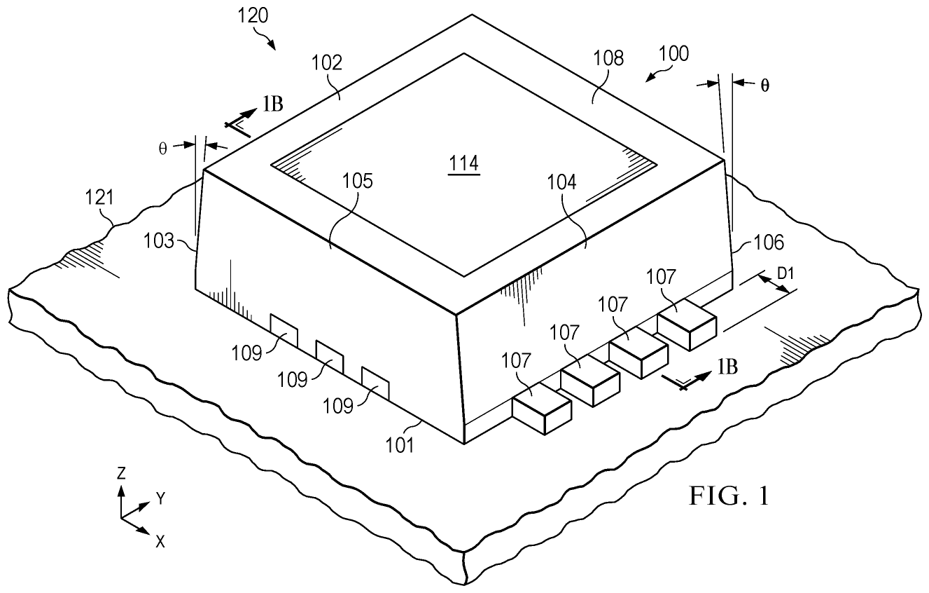

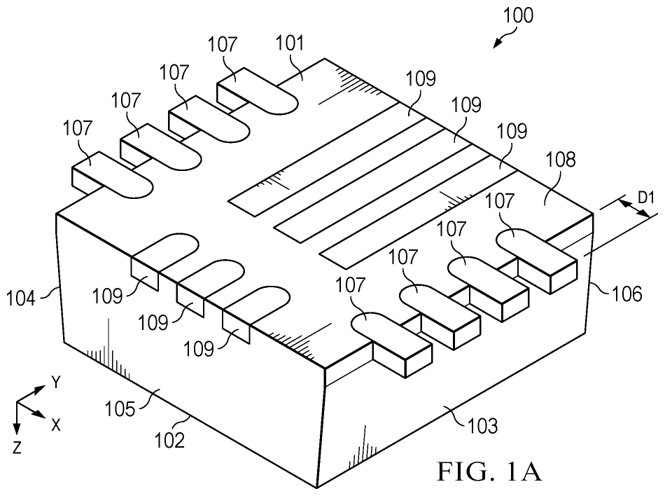

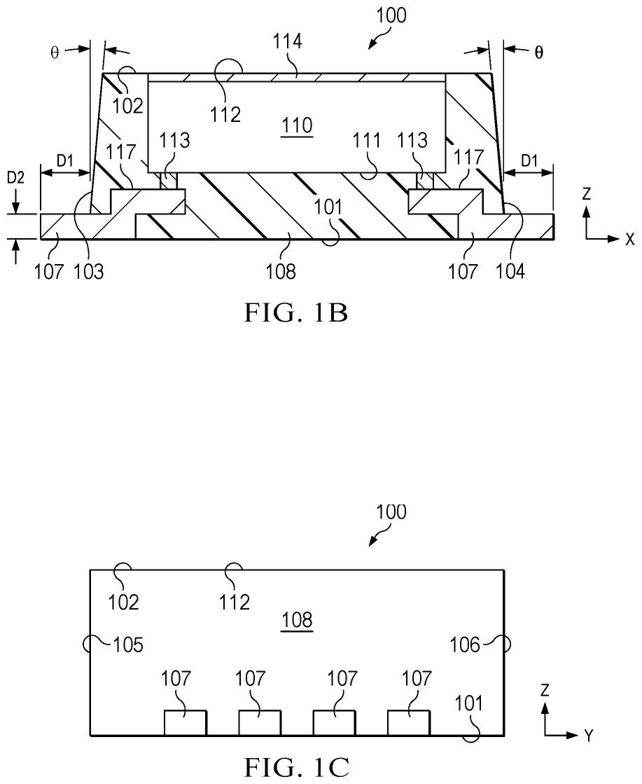

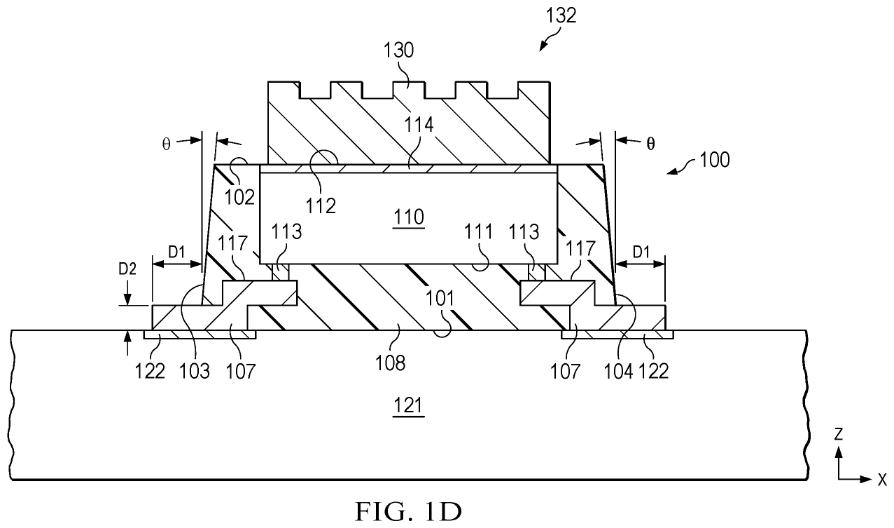

FIGS. 1-1D show an example quad flat package electronic device 100 in a system 120 with leads 107 and 109 soldered to conductive pads of a circuit board 121. The electronic device 100 is positioned in an example three-dimensional space with a first direction X, a perpendicular (orthogonal) second direction Y, and a third direction Z that is perpendicular (orthogonal) to the respective first and second directions X and Y. Structures or features along any two of these directions are orthogonal to one another. The electronic device 100 has opposite first and second (e.g., bottom and top) sides 101 and 102, respectively, which are spaced apart from one another along the third direction Z in the illustrated position. The electronic device 100 also has opposite third and fourth sides 103 and 104 (e.g., lateral sides) that are spaced apart from one another along the first direction X, and fifth and sixth sides 105 and 106 that are spaced apart from one another along the second direction Y in the illustrated position.

The electronic device has a hybrid quad flat package shape or arrangement with conductive metal first leads 107 (e.g., also referred to as stub leads) exposed outside a molded package structure 108 along the bottom or first side 101. The individual first leads 107 extend outward from the molded package structure 108 by a first spacing distance D1 (FIGS. 1-1B) along a respective one of the third and fourth sides 103 and 104. In various example implementations, the electronic device 100 can have any integer number of one or more instances of the first lead 107 extending outward along the first direction X from the molded package structure 108 along the third side 103 and one or more instances of the first lead 107 extending outward along the first direction X from the molded package structure 108 along the fourth side 104.

The electronic device 100 has a first set (e.g., 4 instances) of the first leads 107 that are spaced apart from one another along the second direction Y and extend outward along the first direction X from the molded package structure 108 along the third side 103. The first set of the first leads 107 have respective lateral sides exposed outside the molded package structure 108 along the third side 103. Along the fourth side 104, the illustrated electronic device 100 has a second set (e.g., 4 instances) of the first leads 107 that are spaced apart from one another along the second direction Y and extend outward along the first direction X from the molded package structure 108. The second set of the first leads 107 have respective lateral sides exposed outside the molded package structure 108 along the fourth side 104. The first leads 107 in this example each have a bottom side exposed outside the molded package structure 108 along the first side 101.

As best shown in FIGS. 1 and 1B, the molded package structure 108 has generally flat lateral sides along the third and fourth sides 103 and 104 of the electronic device 100, although not a requirement of all possible implementations. The molded package structure 108 is at a non-zero angle θ to the third direction Z along the respective third and fourth sides 103 and 104. In particular, the respective third and fourth sides 103 and 104 of the molded package structure 108 each extend at the angle θ with respect to the third direction Z, where the angle θ in one example corresponds to draft angles of a mold cavity used in creating the molded package structure 108. In contrast, the fifth and sixth sides 105 and 106 are substantially vertical and extend along the third direction from the bottom or first side 101 to the top or second side 102 as best shown in FIG. 1C.

The electronic device 100 in this example also includes conductive metal second leads 109, also referred to as flush leads, with bottom sides exposed outside the molded package structure 108 along the first (e.g., bottom) side 101. In another implementation, the electronic device has one or more instances of the second leads 109 along only one of the fifth and sixth sides 105 and 106. In yet another example, the second leads 109 are omitted. Various implementations are possible where the electronic device has upset leads with lower and raised portions (flush and/or stub leads) along any two or more of the sides 103-106.

The individual second leads 109 in the illustrated example have a lateral side exposed outside the molded package structure 108 along a respective one of the fifth and sixth sides 105 and 106. In addition, the lateral side of the individual second leads 109 is flush with a respective side of the molded package structure 108 along the respective one of the fifth and sixth sides 105 and 106. In various example implementations, the electronic device 100 can have no or any integer number of one or more instances of the second lead 109 along the fifth side 105 and no or one or more instances of the second lead 109 along the sixth side 106.

The lateral sides of the molded package structure 108 along the fifth and sixth sides 105 and 106 in one example are vertical and planar lying in parallel respective X-Z planes of the first and third directions X and Z in the illustrated orientation, although not a requirement of all possible implementations. The electronic device 100 in the illustrated example has a first set of three instances of the second leads 109 that are spaced apart from one another along the first direction X and have respective lateral sides exposed flush with and outside the molded package structure 108 along the fifth side 105. In addition, the electronic device 100 has a second set of three instances of the second leads 109 that are spaced apart from one another along the first direction X and have respective lateral sides flush with and exposed outside the molded package structure 108 along the sixth side 106. The second set of second leads 109 in one implementation are elongated along the second direction Y as shown in FIG. 1A, although not a requirement of all possible implementations.

As further shown in FIG. 1B, the conductive metal first leads 107 have a lower first portion and a raised second portion 117 and can be referred to as upset leads. The first portion of the respective first leads 107 has a bottom side that is exposed outside the molded package structure 108 along the first side 101. The first portion of each one of the first leads 107 in one example extends outward from the molded package structure 108 by the non-zero distance D1 along a respective one of the third and fourth sides 103 and 104. The second portion 117 of the respective first leads 107 is enclosed by the molded package structure 108 and spaced apart from the first side 101 by a non-zero second distance D2.

The leads 107 and 109 in the illustrated example are or include copper, aluminum, or other suitable metal or alloys thereof. In the example of FIGS. 1 and 1A, the individual second leads 109 have a bottom side exposed outside the molded package structure 108 along the first side 101, and the second leads 109 have a uniform thickness along the third direction Z, although not a requirement of all possible implementations. In another example, one or more of the second leads 109 (if included) can have lower first portions and raised second portions that are spaced apart from the lower first side 101 (e.g., by the second distance D2 or by a different amount).

As best shown in FIG. 1B, the electronic device 100 includes a semiconductor die 110 with a bottom or first side 111 and a top or second side 112. The semiconductor die 110 has one or more conductive metal terminals 113, such as copper pillars or posts that extend outward along the third direction Z from the first side 111 of the semiconductor die 110. The semiconductor die 110 in the illustrated example is flip chip soldered to one or more of the leads 107, 109, such as by solder connections (not shown) that solder bottoms of the terminals 113 to respective ones of the leads 107 and/or 109. The example terminals 113 shown in the sectional view of FIG. 1B are connected to the second portion 117 of the respective first leads 107, and similar flip chip solder connections (not shown) may be made between other terminals 113 of the semiconductor die 110 to raised or second portions of one or more of the second leads 109.

The semiconductor die 110 includes a backside metal structure 114 along the second side 112 of the semiconductor die 110. The backside metal structure 114 is exposed outside the molded package structure 108 along the second side 102 as best shown in FIGS. 1 and 1B. In one example, the top side 112 of the backside metal structure 114 is approximately coplanar with the plane of the top side 102 of the molded package structure, although not a requirement of all possible implementations.

With reference to FIGS. 1 and 1D, the exposed backside metal structure 114 in certain examples operates as a thermal pad that can help remove heat from the semiconductor die 110 and electronic components thereof. The system 120 shown in FIG. 1 includes the electronic device 100 mounted on a printed circuit board 121, with the backside metal structure 114 exposed outside the top side 102 to allow airflow across the backside metal 114. FIG. 1D shows another system 132 with the example electronic device 100 mounted on the printed circuit board 121 with bottoms of the first portions of the illustrated conductive first leads 107 soldered to conductive metal pads 122 of the circuit board 121. In this example, a heatsink 130 is attached (e.g., by soldering, thermally conductive adhesive, etc.) to the backside metal structure 114 of the semiconductor die 110. The heatsink 130 in this example includes upper fins or ribs to facilitate extraction of heat from the backside metal structure 114 to the ambient environment of the system.

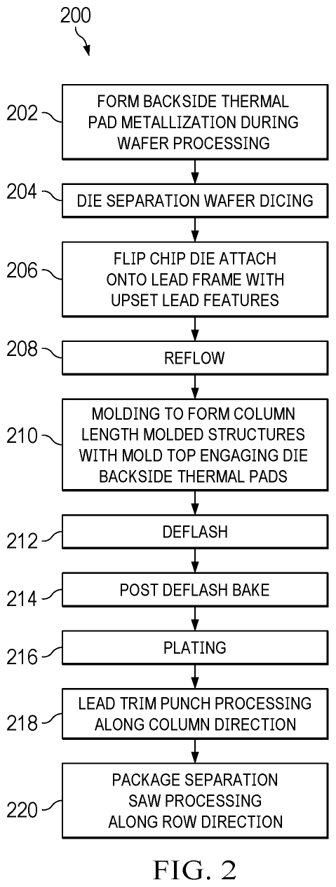

As discussed further below in connection with FIG. 2, the use of upset first and/or second leads 107, 109 facilitates molding operations during device manufacturing to expose the backside metal structure 114 formed during wafer processing. For example, the upset structure of the first and/or second leads 107, 109 provides an upward spring force to the semiconductor die 110 that facilitates engagement of an upper mold portion with the backside metal structure 114 during injection and curing of molding compound. Proper engagement of the mold structure to the pre-existing backside metal structure 114 mitigates or avoids mold flash or over molding and the need for subsequent mold flash removal processing during manufacturing.

These advantages facilitate cost reduction in device fabrication compared with intentional over molding and subsequent mold material removal and plating to form backside metal on the back side of the semiconductor die. The illustrated examples enable low-cost metallization at the wafer level to form the backside metal structure 114 prior to die singulation, and the spring force provided by the upset lead structures facilitates mold engagement with the previously formed backside metal structure 114 even in the presence of device height and tolerance variations (e.g., lead frame thickness variations, die thickness variations, die terminal thickness variations, etc.).

In addition, the illustrated examples facilitate reduced manufacturing cost by use of the upset stub leads (e.g., first leads) 107 alone or in combination with flush second leads 109 that can also include upset structures to help ensure mold engagement to the backside metal structure 114 during molding. The illustrated structures can be manufactured using column-length mold cavities to facilitate high units per strip (UPS) to further reduce cost and enhance manufacturing robustness. The example electronic device structures and fabrication methods provide advantages compared to the alternative solution to expose die backside by grinding process then deposit metal on backside of die, but this is a complicated process flow with adding multiple processing steps to original flow, and there is a risk of grind and hard to deposit metal on die backside at strip/package level. The illustrated examples, moreover, can mitigate or avoid the cost and complexity associated with film assisted molding used in conventional saw QFN manufacturing.

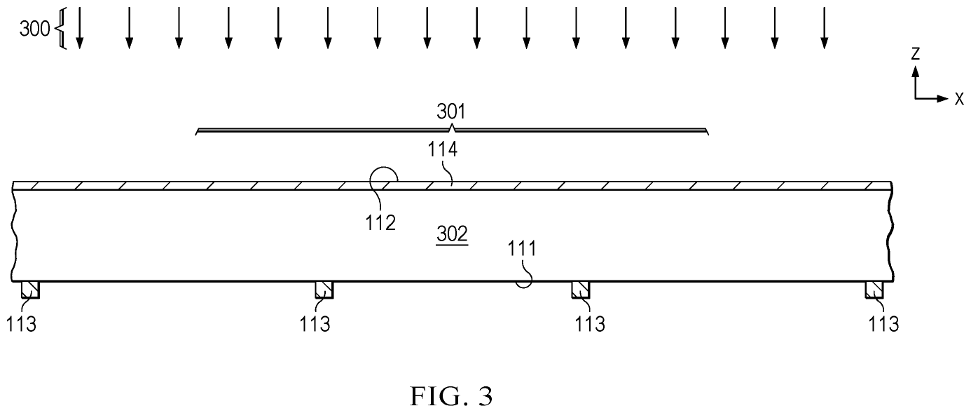

Referring now to FIGS. 2-13, FIG. 2 shows a method 200 for making an electronic device according to another aspect and FIGS. 3-13 shows the example electronic device 100 at various stages of fabrication according to the method 200. The method 200 is illustrated during wafer processing to provide an instance of the semiconductor die 110 in each of multiple prospective die areas of a starting wafer as well as subsequent packaging operations using a starting lead frame with multiple unit areas arranged in rows and columns of a lead frame panel array structure.

The example method 200 begins at 202 in FIG. 2 with wafer level backside metallization processing to form a backside thermal pad in each unit of a wafer. FIG. 3 shows one example, in which a metallization process 300 is performed to form the backside metal structure 114 along the second side 112 of a die area 301 of a wafer 302. In this example, transistors and other electronic components have previously been formed on and/or in the semiconductor wafer 302, and the conductive metal terminals 113 (e.g., copper pillars or posts) have been formed along the first side 111 of the wafer 302.

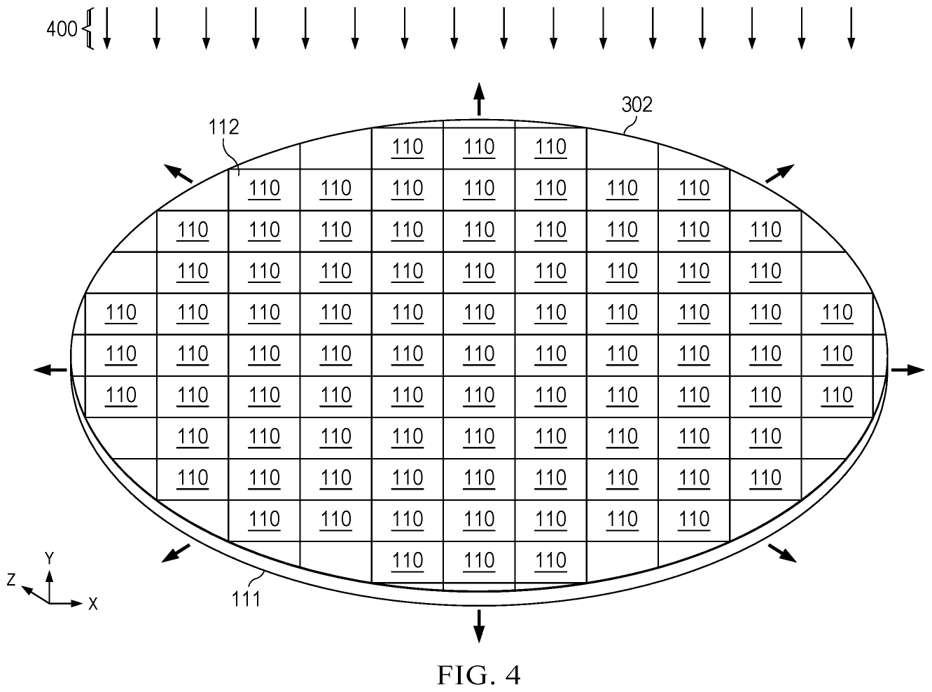

At 204 in FIG. 2, the method 200 includes die separation by wafer dicing or other suitable technique. FIG. 4 shows one example, in which a die separation process 400 is performed that separates individual instances of the semiconductor die 110 from the wafer 302. In one example, a laser dicing process is used to create cracks along scribe streets between adjacent die areas of the wafer, and radially outward stretching tension is applied as indicated by the radial arrows in FIG. 4 to a carrier tape (not shown) on which the wafer is mounted to separate the individual semiconductor dies 110 from the starting wafer structure.

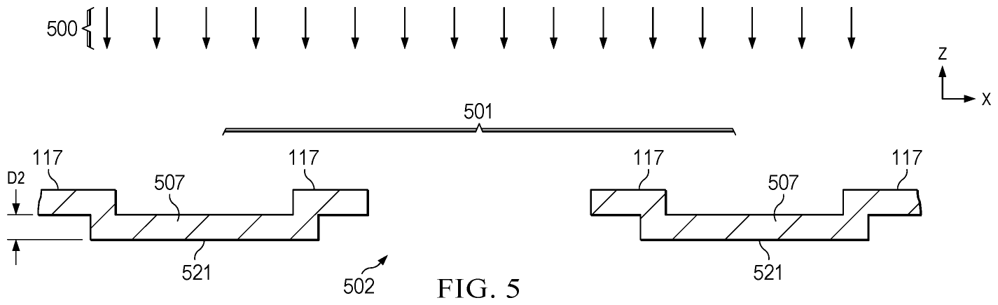

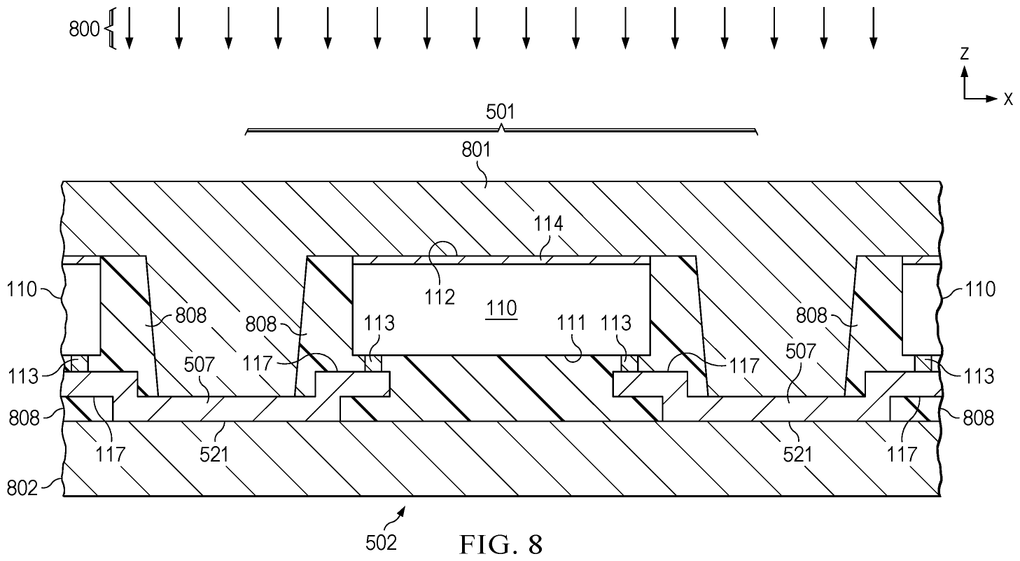

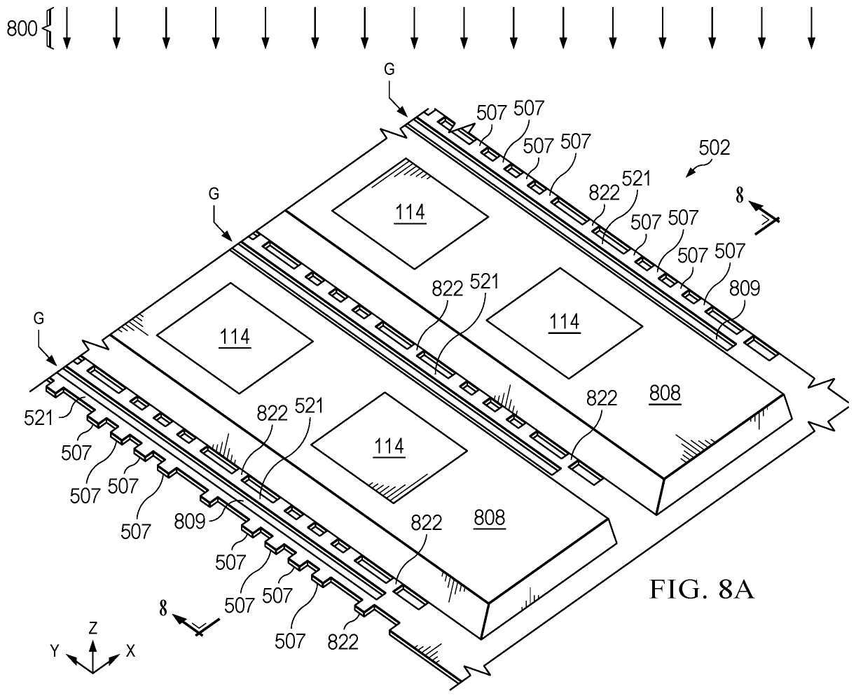

After die separation, the method 200 continues at 206 with die attachment. FIG. 5 shows an example lead frame fabrication process 500 that creates a lead frame 502 with unit areas 501 arranged in an array with rows along a first direction X and columns along an orthogonal second direction (e.g., into the page in FIG. 5, second direction Y shown in FIG. 8A below). The lead frame 502 in one example has conductive metal features and the lead frame 502 is designed for molding operations with a mold having column-wise cavities extending along the second direction Y. The lead frame 502 can be or include any suitable conductive metal, such as copper, aluminum, alloys thereof, etc. The lead frame 502 can be fabricated using any suitable fabrication process 500 and equipment, including stamping, etching and/or combinations thereof to form the conductive metal structures.

The individual unit areas 501 can include one or more conductive metal features corresponding to prospective conductive leads suitable for attachment of one or more semiconductor dies by flip chip soldering within the respective unit areas 501. The individual unit areas 501 in this example have one or more conductive features which correspond to prospective leads of the finished electronic device as well as internal tie bars along the row and column directions between adjacent unit areas 501. The individual unit areas 501 have prospective first leads 507 along two opposite lateral sides of the unit area 501 that are spaced apart from one another along the first direction X, and prospective second leads (not shown in FIG. 5) along two opposite lateral ends of the unit area 501 that are spaced apart from one another along the second direction Y. The prospective leads 507 in this example have first portions with a lower surface that extend in a lead frame plane and are coplanar with one another to facilitate soldering of the finished electronic devices to a host circuit board (not shown), as well as raised features, such as half etch features, for example, to accommodate upset leads 507 with raised second portions 117, tie bars, dam bars, etc., having bottom sides that are not coplanar with the bottom sides of the prospective leads 507.

The lead frame panel array 502 has first tie bars 521 that extend along the second direction Y between adjacent columns, and the respective first tie bars 521 are connected to the prospective first leads 507 of the unit areas 501 along a column of the array. The illustrated example, moreover, includes gaps G (FIG. 8A below) between adjacent pairs of the first tie bars 521 or portions thereof, for example, to mitigate lead frame warping or deformation during handling in a manufacturing process. As further shown in FIG. 8A below, the lead frame 502 in one example also includes second tie bars 822 that extend along the first direction X between adjacent rows of the array configuration, and the second tie bars 822 are connected to the prospective second leads along adjacent rows of the array.

In one example, each unit area 501 has prospective upset first leads 507 along two opposite lateral sides of the unit area 501 that are spaced apart from one another along the first direction X. The lead frame 502 in one example also includes prospective second leads along two opposite lateral ends of the unit area 501 that are spaced apart from one another along the second direction Y. Each prospective first lead 507 in this example has a lower first portion and a raised second portion 117 (e.g., as described above and shown in FIGS. 1B and 1D), where the first portion has a bottom side and the second portion 117 has a bottom side spaced apart from the bottom side of the first portion by the non-zero distance D2. The first portions of the prospective first leads 507 of unit areas 501 in adjacent columns of the lead frame 502 are joined by respective first tie bars 521 that are contiguous with and connected to the prospective first leads 507 of the unit areas 501 along each row of the array.

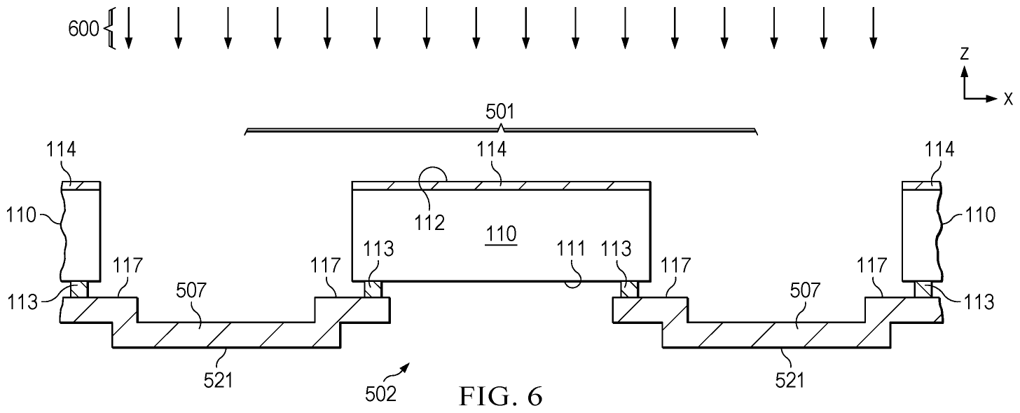

FIG. 6 shows an example in which a die attach process 600 is performed that mounts an instance of the semiconductor die 110 respective unit areas 501 of the lead frame 502. The example die attach process 600 mounts a semiconductor die 110 with the conductive terminals 113 engaging raised second portions 117 of respective prospective leads 507 in one or more of the individual unit areas 501 of the lead frame 502. The die attach process 502 can include, for example, dispensing, printing, or otherwise providing solder or conductive or nonconductive adhesive in select portions of top sides of certain lead frame features or providing plated or dispensed solder to the ends of the terminals 113 prior to attachment of semiconductor dies 110, for example, using automated pick and place equipment (not shown) to mounting the first side 111 of a semiconductor die 110 onto individual unit areas 501 of the lead frame 502. In another example, the semiconductor die 110 can be attached to a die attach pad (not shown) of the unit area 501 for subsequent wire bond connections (not shown).

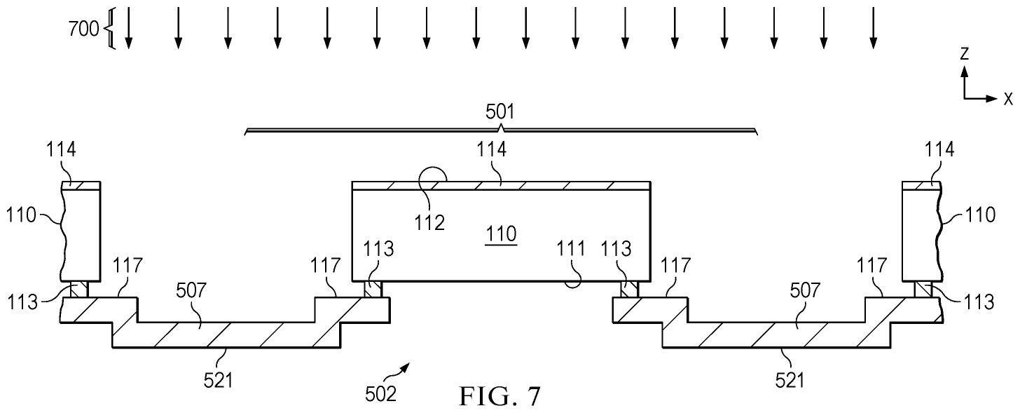

The method 200 continues at 208 with electrically connecting the conductive terminals 113 along the first side 111 of the semiconductor die 110 to the raised second portions 117 of the respective prospective first leads 507, FIG. 7 shows one example, in which a thermal reflow process 700 is performed that creates solder connections of the bottoms of the conductive terminals 113 to the respective prospective first leads 507 in each unit area 501 of the lead frame 502. In another implementation, bond wires (not shown) can be formed to create electrical connections between lead frame features and the semiconductor die 110 to provide desired electrical circuit connections in each unit area 501. The illustrated processes 600 and 700 in FIGS. 6 and 7 in one example are a flip chip die attach process 600 and a solder reflow process 700.

The method 200 continues at 210 in FIG. 2 with molding to form column length molded structures with a mold top engaging all or portions of the die backside metal structures 114 (e.g., thermal pads). FIGS. 8 and 8A show one example, in which a molding process 800 is performed with a mold (FIG. 8) having a first mold portion 801 that engages the backside metal structure 114 along the second side 112 of the semiconductor die 110 and a second mold portion 802 that engages bottom sides of lower first portions of the prospective first leads 507 in each unit area 501 of the lead frame panel array. The molding process 800 forms a molded package structure 808 (e.g., also referred to as a mold bar) that extends through multiple unit areas 501 along each column of the lead frame 502.

FIG. 8A a shows the lead frame array structure with the mold removed, where the molded package structure 808 exposes the backside metal structure 114. The molded package structure 808 in each column also encloses the second portions 117 of the prospective first leads 507 and exposes the bottom sides of the lower first portions of the prospective first leads 507 in each unit area 501. In one example, as shown in FIG. 8A, the lead frame 502 includes gaps G extending between column direction tie bar portions 521. In another implementation, the gaps G can be of different shapes and/or can be omitted. Where the individual unit areas 501 of the lead frame 502 include one or more prospective second leads along two opposite lateral ends of the unit area 501 that are spaced apart from one another along the second direction Y (not shown in FIGS. 8 and 8A), the molded package structure 808 formed at 210 encloses the prospective second leads in the unit area 501.

As discussed above, the provision of upset prospective first (e.g., and second) leads 507 provides a spring force that biases the semiconductor die 110 upward to facilitate complete engagement of the top surface of the backside metal structures 114 against the first mold portion 801 (FIG. 8). Proper engagement of the first mold portion 801 to the backside metal structure 114 mitigates or avoids mold flash or over molding and the need for subsequent mold flash removal processing during manufacturing.

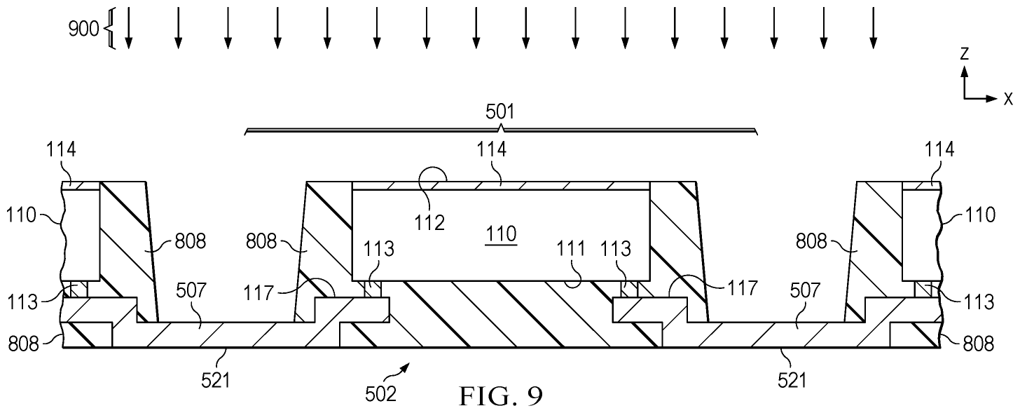

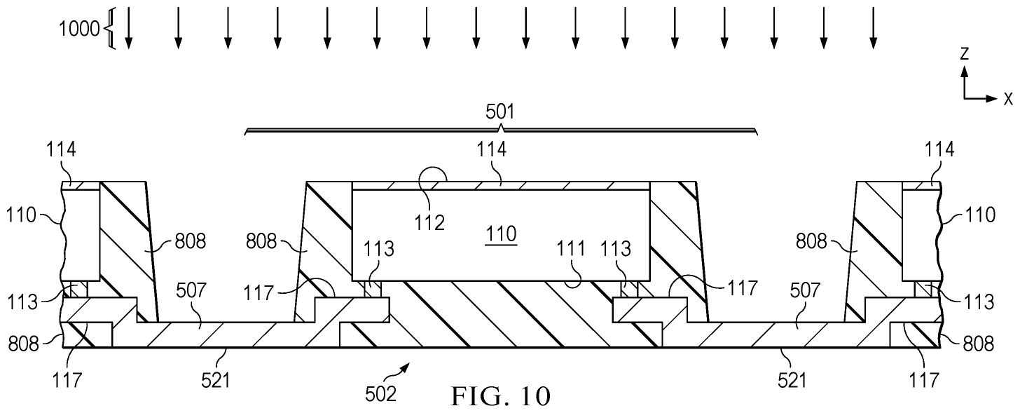

If any mold flash remains along the backside metal structures 114 after the molding process at 210, the method 200 in FIG. 2 can include optional deflash processing at 212. FIG. 9 shows one example, in which a mold flash removal process 900 (e.g., laser ablation, chemical etching, mechanical material removal processing, etc.) is performed that removes any remnant mold compound or molding material from the top side of the backside metal structures 114 in each unit area 501. In this example, the method 200 may include a post deflash bake step at 214. FIG. 10 shows one example, in which a thermal heating or baking process 1000 is performed. In another implementation, the deflash processing at 212 and baking step at 214 can be omitted.

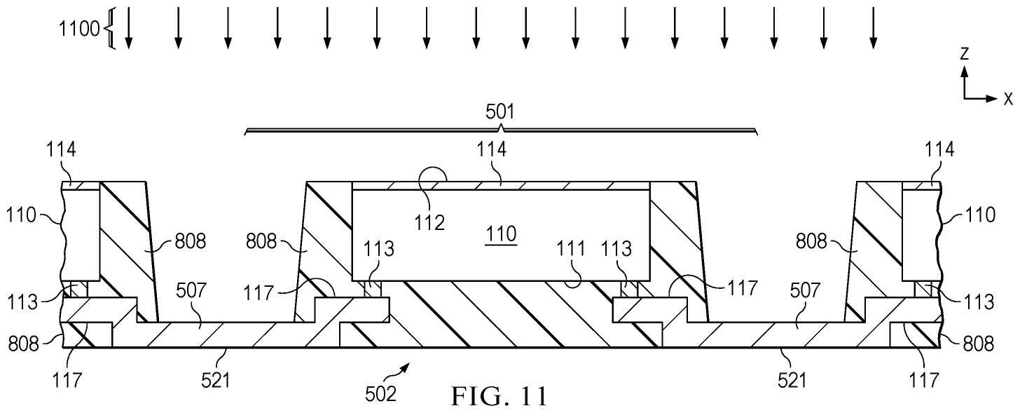

At 216 in FIG. 2, an optional plating step can be used to played exposed surfaces of the lead frame 502. FIG. 11 shows one example, in which a plating process 1100 is performed (e.g., electroplating) to plate the exposed surfaces of the prospective first leads 507 including the exposed tie bars 521. In another implementation, the plating processing at 216 can be omitted.

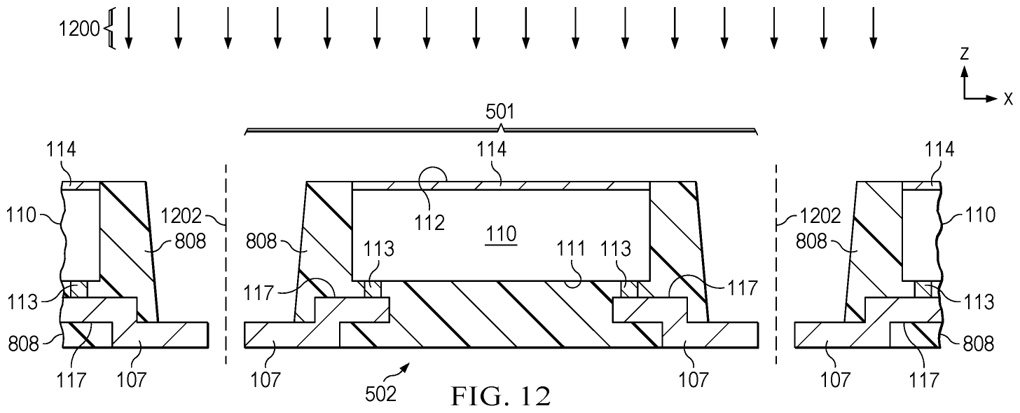

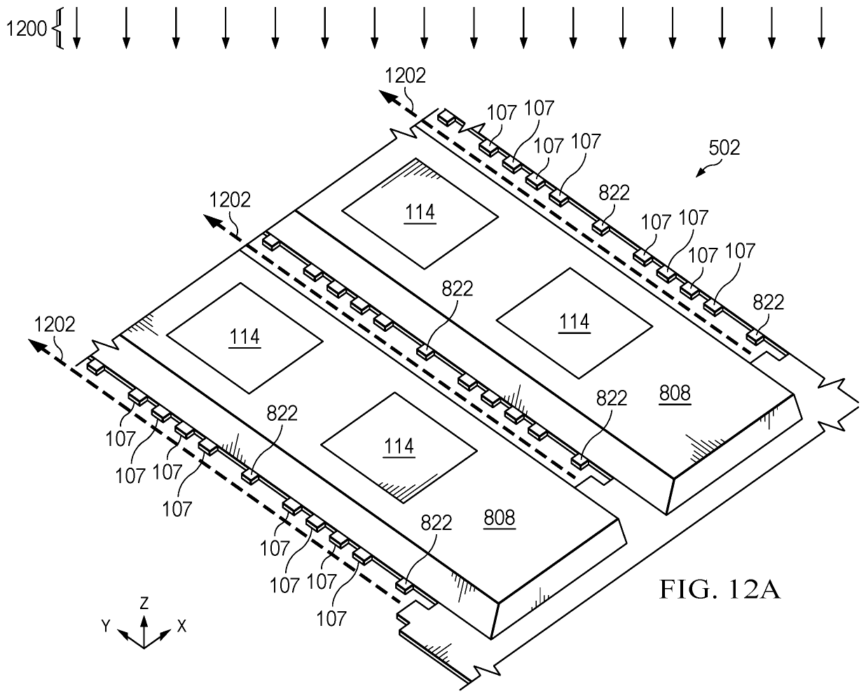

The method 200 continues at 218 in FIG. 2 with lead trim punch processing along the column direction to separate adjacent columns of the lead frame panel array 502. FIGS. 12 and 12A show one example, in which a column direction separation process 1200 is performed that separates each column along the lines 1202 from an adjacent second column of the lead frame 502 along the second direction Y. The separation process 1200 includes lead trimming and optional lead forming using suitable equipment (e.g., punch dies, etc.) to form the ends of the first leads 107 with the lower first portions and the raised second portions 117 along the two opposite lateral sides of each unit area 501. In one example, the separation process 1200 is or includes use of punch die equipment (not shown) that trims the prospective first leads in the first tie bars 521 (e.g., FIG. 5 above) that originally extended between laterally neighboring unit areas 501 to form the first (e.g., stub) leads 107 that extend outward from the lateral sides of the molded structures 808 along each column of the lead frame array 502.

In another example, the separation process 1200 can include a saw blade cutting operation using one or more cutting blades (not shown), such as a single cutting blade performing one cut at a time along the respective lines 1202. In another implementation, laser cutting and/or other separation steps can be used alone or in combination with punching or other operations to perform single or multiple pass separation along the lines 1202.

In these or another example, the separation process 1200 can include punching operations and/or other processing to form separated leads along the lateral sides of the unit areas 501 into a desired shape, such as j-leads, gullwing leads, etc. (not shown). In the above or another implementation, the method can include optional plating operations after lead trimming and forming at 218, for example, to plate the exposed surfaces of the trimmed first leads 107 and the bottoms of the prospective second leads 109 (FIG. 1A above) to provide fully and/or partially plated leads in the finished electronic device of each unit area 501. The separation process 1200 in this example separates each individual column from an adjacent second column of the lead frame 502 along the second direction Y to form first leads 107 along the two opposite lateral sides of the individual unit areas 501.

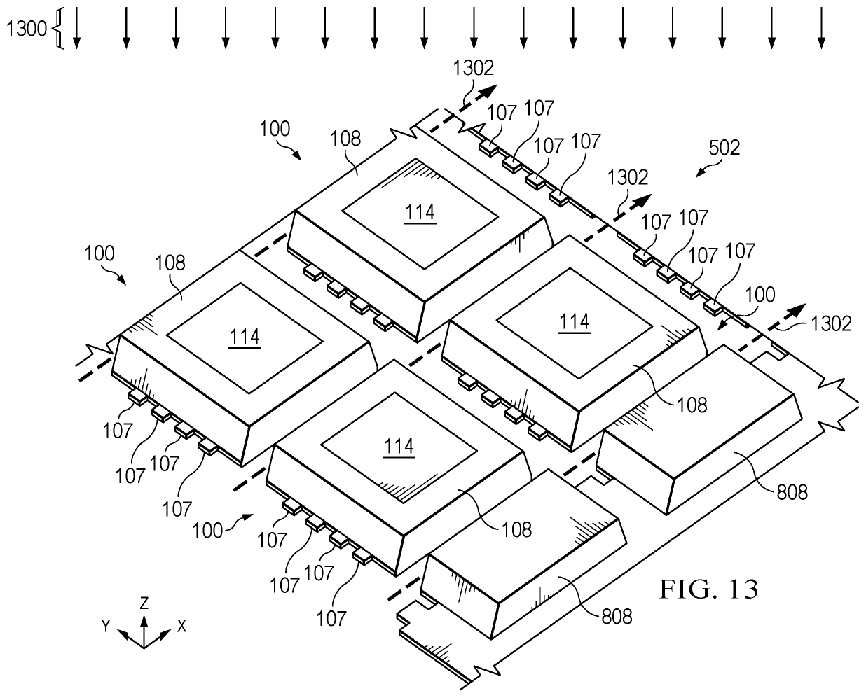

The method 200 continues at 220 in FIG. 2 with row direction package separation to separate individual packaged electronic devices 100 from one another along each column in the array. FIG. 13 shows one example, in which a separation process 1300 is performed (e.g., saw blade cutting, laser cutting, chemical etching, combinations thereof, etc.). The separation process 1300 separates finished packaged electronic devices 100 and adjacent rows and unit areas 501 of each column from one another along lines and from the lead frame 502 along lines 1302 (e.g., along the first direction X). In one example, the separation process 1300 includes a saw or laser cutting process 1300 that cuts through the molded structure 808 and the prospective second leads to form the second leads 109 (e.g., FIGS. 1 and 1A above, not shown in the view of FIG. 13) along the two opposite lateral ends of the unit area 501 which separates each molded structure 808 into individual molded packages structures 108. An optional step, not shown, after packaged electronic device separation includes plating the cut and now exposed vertical sidewall surface of leads 109 on selected individual packaged electronic devices 100 to inhibit oxidation, and enhance solderability, of the vertical sidewall surface of the leads 109.

Modifications are possible in the described examples, and other implementations are possible, within the scope of the claims.

What is claimed is:

1. An electronic device, comprising:
opposite first and second sides;
opposite third and fourth sides;
a molded package structure;
a semiconductor die having a backside metal structure exposed outside the molded package structure along the second side; and
conductive metal first leads along the third and fourth sides, each one of the first leads having a first portion and a second portion, the first portion having a side exposed outside the molded package structure along the first side, and the second portion enclosed by the molded package structure and spaced apart from the first side by a non-zero distance.

2. The electronic device of claim 1, wherein the first portion of each one of the first leads extends outward from the molded package structure by another non-zero distance along a respective one of the third and fourth sides.

3. The electronic device of claim 2, wherein:
the opposite third and fourth sides are spaced apart from one another along a first direction;
the electronic device further comprises opposite fifth and sixth sides spaced apart from one another along a second direction that is orthogonal to the first direction;
the first and second sides are spaced apart from one another along a third direction that is orthogonal to the first and second directions; and
the molded package structure is at a non-zero angle to the third direction along the third and fourth sides.

4. The electronic device of claim 3, further comprising conductive metal second leads exposed outside the molded package structure along the first side, each one of the second leads having a lateral side exposed outside the molded package structure along a respective one of the fifth and sixth sides, and the lateral side of the individual second leads being flush with a respective side of the molded package structure along the respective one of the fifth and sixth sides.

5. The electronic device of claim 4, wherein the molded package structure along the fifth and sixth sides is planar and extends in a plane of the first and third directions.

6. The electronic device of claim 1, wherein:
the opposite third and fourth sides are spaced apart from one another along a first direction;
the electronic device further comprises opposite fifth and sixth sides spaced apart from one another along a second direction that is orthogonal to the first direction;
the first and second sides are spaced apart from one another along a third direction that is orthogonal to the first and second directions; and
the molded package structure is at a non-zero angle to the third direction along the third and fourth sides.

7. The electronic device of claim 6, wherein the molded package structure along the fifth and sixth sides is planar and extends in a plane of the first and third directions.

8. The electronic device of claim 1, further comprising:
opposite fifth and sixth sides; and
conductive metal second leads exposed outside the molded package structure along the first side, each one of the second leads having a lateral side exposed outside the molded package structure along a respective one of the fifth and sixth sides, and the lateral side of the individual second leads being flush with a respective side of the molded package structure along the respective one of the fifth and sixth sides.

9. The electronic device of claim 1, wherein:
the semiconductor die has a first side with a conductive terminal, and an opposite second side, the backside metal structure extending along the second side of the semiconductor die; and
the conductive terminal is connected to the second portion of one of the first leads.

10. A system, comprising:
a circuit board having conductive metal pads; and
an electronic device attached to the circuit board and comprising:
opposite first and second sides,
opposite third and fourth sides,
a molded package structure,
a semiconductor die having a backside metal structure exposed outside the molded package structure along the second side, and
conductive metal first leads along the third and fourth sides, each one of the first leads having a first portion and a second portion, the first portion having a side exposed outside the molded package structure and connected to a respective one of the conductive metal pads along the first side, and the second portion enclosed by the molded package structure and spaced apart from the first side by a non-zero distance.

11. The system of claim 10, wherein the first portion of each one of the first leads extends outward from the molded package structure by another non-zero distance along a respective one of the third and fourth sides.

12. The system of claim 10, wherein:
the opposite third and fourth sides are spaced apart from one another along a first direction;
the electronic device further comprises opposite fifth and sixth sides spaced apart from one another along a second direction that is orthogonal to the first direction;
the first and second sides are spaced apart from one another along a third direction that is orthogonal to the first and second directions; and
the molded package structure is at a non-zero angle to the third direction along the third and fourth sides.

13. The system of claim 12, wherein the molded package structure along the fifth and sixth sides is planar and extends in a plane of the first and third directions.

14. The system of claim 10, further comprising:
opposite fifth and sixth sides; and
conductive metal second leads exposed outside the molded package structure along the first side, each one of the second leads having a lateral side exposed outside the molded package structure along a respective one of the fifth and sixth sides, and the lateral side of the individual second leads being flush with a respective side of the molded package structure along the respective one of the fifth and sixth sides.

15. The system of claim 10, wherein:
the semiconductor die has a first side with a conductive terminal, and an opposite second side, the backside metal structure extending along the second side of the semiconductor die; and
the conductive terminal is connected to the second portion of one of the first leads.

16. The system of claim 10, further comprising a heat sink attached to the backside metal structure of the semiconductor die.

17. A method fabricating an electronic device, the method comprising:
mounting a first side of a semiconductor die on a unit area of a lead frame;
electrically connecting conductive terminals along the first side of the semiconductor die to raised second portions of respective prospective first leads along two opposite lateral sides of the unit area that are spaced apart from one another along a first direction;
performing a molding process with a mold having a first mold portion (801) that engages a backside metal structure along an opposite second side of the semiconductor die and a second mold portion that engages bottom sides of lower first portions of the prospective first leads in the unit area to form a molded package structure that extends through multiple unit areas along a column of the lead frame, exposes the backside metal structure, encloses the second portions of the prospective first leads, and exposes the bottom sides of the lower first portions of the prospective first leads in the unit area;
separating the column from an adjacent second column of the lead frame along an orthogonal second direction to form first leads with the lower first portions and the raised second portions along the two opposite lateral sides of the unit area; and
cutting through the molded package structure along the first direction to separate an electronic device of the unit area from the lead frame.

18. The method of claim 17, further comprising, before mounting the semiconductor die on the unit area of the lead frame:
performing a metallization process to form the backside metal structure along the second side of a die area of a wafer; and
separating the semiconductor die from the wafer.

19. The method of claim 17, further comprising, after performing the molding process, removing molding material from the backside metal structure.

20. The method of claim 17, wherein mounting the semiconductor die on the unit area of the lead frame and electrically connecting the conductive terminals of the semiconductor die to the raised second portions of the respective prospective first leads of the unit area includes performing a flip chip die attach process and a solder reflow process.

21. The method of claim 17, wherein:
the lead frame has prospective second leads along two opposite lateral ends of the unit area that are spaced apart from one another along the second direction;
the molded package structure encloses the prospective second leads in the unit area; and
cutting through the molded package structure along the first direction includes cutting through the prospective second leads to form second leads along two opposite lateral sides of the electronic device.

22. A lead frame, comprising:
unit areas arranged in an array with rows along a first direction and columns along an orthogonal second direction, each unit area having prospective first leads along two opposite lateral sides of the unit area that are spaced apart from one another along the first direction, and prospective second leads along two opposite lateral ends of the unit area that are spaced apart from one another along the second direction, each prospective first lead having a lower first portion and a raised second portion, the first portion having a bottom side, and the second portion having a bottom side spaced apart from the bottom side of the first portion by a non-zero distance;
first tie bars connected to the prospective first leads of the unit areas along a row of the array; and
second tie bars connected to the prospective second leads along adjacent rows of the array.
